(19) United States
(12) Patent Application Publication
(10) Pub. No.: US 2016/0081199 A1
(43) Pub. Date: Mar. 17, 2016

(54) PRINTED CIRCUIT BOARD (PCB) AND MANUFACTURING METHOD THEREOF

(71) Applicant: SAMSUNG ELECTRO-MECHANICS CO., LTD., Suwon-Si (KR)

(72) Inventor: Jung Youn KIM, Suwon-Si (KR)

(21) Appl. No.: 14/794,559

(22) Filed: Jul. 8, 2015

(30) Foreign Application Priority Data
Sep. 16, 2014 (KR) 10-2014-0122778

(51) Int. Cl. H05K 3/40; H05K 1/11; H05K 3/10

(52) U.S. Cl. CPC H05K 3/4007; H05K 3/10; H05K 1/111

(57) ABSTRACT

A manufacturing method of a printed circuit board (PCB), including: forming a conductive metal layer on a substrate having conductive pads exposed on one surface of the substrate; melting the conductive metal layer in a heat treatment; and forming solder bumps by concentrating portions of the melted conductive metal layer on the conductive pads, respectively.

### CROSS-REFERENCE TO RELATED APPLICATION

This application claims the priority and benefit of Korean Patent Application No. 10-2014-0122778 filed on Sep. 16, 2014, with the Korean Intellectual Property Office, the disclosure of which is incorporated herein by reference.

### BACKGROUND

The present inventive concept relates to a printed circuit board (PCB) and a manufacturing method thereof.

In a commonly used scheme in which a semiconductor chip is mounted on a surface, solder bumps for forming electrical connections between the semiconductor chip and the PCB have commonly been used in accordance with the recent trend for the miniaturization and thinning of electronic devices.

As input/output (I/O) between the PCB and the semiconductor chip is increased, the solder bumps are required to have a fine pitch therebetween.

### RELATED ART DOCUMENT

(Patent Document 1) Korean Patent Laid-Open Publication No. 2012-0069987

### SUMMARY

An aspect of the present inventive concept may provide a printed circuit board (PCB) capable of securing a high degree of alignment between conductive pads and solder bumps and achieving a fine pitch between the solder bumps, and a manufacturing method thereof.

According to an aspect of the present inventive concept, a manufacturing method of a PCB may include: forming a conductive metal layer on a substrate having conductive pads exposed on one surface of the substrate; melting the conductive metal layer in a heat treatment; and forming solder bumps by concentrating portions of the melted conductive metal layer on the conductive pads, respectively.

According to another aspect of the present inventive concept, a PCB may include: a substrate having conductive pads exposed on one surface of the substrate; and solder bumps formed on the conductive pads, respectively, wherein each of the solder bumps has a curved upper surface, and an interval between the solder bumps is 100 micrometers (μm) or less.

### BRIEF DESCRIPTION OF DRAWINGS

The above and other aspects, features and other advantages of the present inventive concept will be more clearly understood from the following detailed description taken in conjunction with the accompanying drawings, in which:

FIG. 1 is a cross-sectional view illustrating a structure of a printed circuit board (PCB) according to an exemplary embodiment of the present inventive concept;

FIG. 2 is a flowchart illustrating a process of a manufacturing method in which solder bumps of a PCB according to an exemplary embodiment of the present inventive concept are formed; and

FIGS. 3 through 9 are view illustrating sequential operations of a process of forming solder bumps of a PCB according to exemplary embodiments of the present inventive concept.

### DETAILED DESCRIPTION

Exemplary embodiments of the present inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

As used herein, it will be further understood that the terms “include” and/or “have” when used in the present inventive concept, specify the presence of elements, but do not preclude the presence or addition of one or more other elements, unless otherwise indicated.

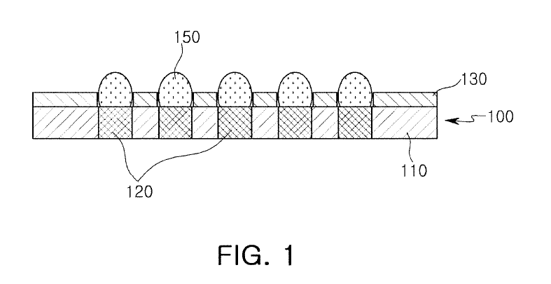

FIG. 1 is a cross-sectional view illustrating a structure of a printed circuit board (PCB) according to an exemplary embodiment of the present inventive concept.

Referring to FIG. 1, a PCB according to an exemplary embodiment of the present inventive concept may include: a substrate 100 having conductive pads 120 exposed on one surface of the substrate 100; and solder bumps 150 formed on the conductive pads 120, respectively.

Insulation portions 110 may be formed between the conductive pads 120, and solder resists 130 may be disposed on a surface of the substrate 100 including the conductive pads 120 and the insulation portions 110 therein to expose the solder bumps 150.

In the PCB manufactured according to the exemplary embodiment of the present inventive concept, each of the solder bumps 150 may have a curved upper surface, and an interval between the solder bumps 150 may be 100 micrometers (μm) or less.

According to the exemplary embodiment of the present inventive concept, the solder bumps may not be formed to correspond to the conductive pads 120, respectively, but may be formed in an auto alignment scheme using hydrophilicity of a metal by forming a conductive metal layer on an entire region in which the solder bumps are to be formed, and melting the conductive metal layer in a heat treatment, such that a high degree of alignment between the conductive pads 120 and the solder bumps 150 may be secured, and the interval between the solder bumps 150 may be 100 μm or less, that is, a fine pitch between the solder bumps 150 may be achieved.

A description pertaining to a manufacturing method of a PCB according to an exemplary embodiment of the present inventive concept will be provided in detail later.

The conductive pads 120 may be formed of any conductive metals as long as they are able to be used for circuit patterns, without being particularly limited. For example, the conductive pads 120 may be formed of copper (Cu)

As the insulation portion 110, a resin insulation layer may be used. The resin insulation layer may be formed of thermosetting resins such as an epoxy resin, thermoplastic resins such as polyimide, resins impregnated with reinforcing materials such as glass fibers or inorganic fillers, for example, pre-impregnated composite fibers (pre-preg). However, the type of material forming the resin insulation layer is not particularly limited thereto.

The solder bumps 150 may further contain at least one selected from the group consisting of Cu, silver (Ag), gold (Au), aluminum (Al), iron (Fe), titanium (Ti), tin (Sn), nickel (Ni) and molybdenum (Mo).

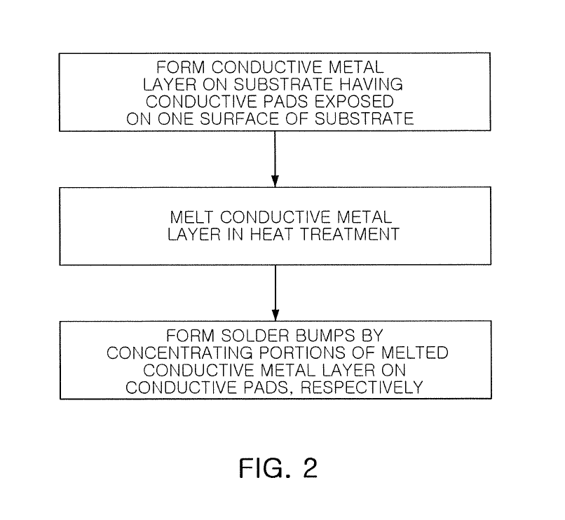

FIG. 2 is a flowchart illustrating a process of a manufacturing method in which solder bumps of a PCB according to an exemplary embodiment of the present inventive concept are formed.

Referring to FIG. 2, the solder bumps 150 of the PCB according to the exemplary embodiment of the present inventive concept may be manufactured by forming the conductive metal layer on the substrate 100 having the conductive pads 120 exposed on one surface of the substrate 100, melting the conductive metal layer in a heat treatment, and forming the solder bumps 150 by concentrating portions of the melted conductive metal layer on the conductive pads 120, respectively.

In another exemplary embodiment in which solder bumps are formed, the solder bumps may be formed by patterning metal masks or plating resists to correspond to the conductive pads 120, respectively, and by using a solder paste or performing an electroplating. In this case, since it is difficult to process the metal masks or the plating resists to correspond to highly integrated and fine pads, respectively, a degree of alignment between the conductive pads 120 and the solder bumps to be formed may be deteriorated.

Accordingly, in the exemplary embodiment of the present inventive concept, the solder bumps may not be formed by patterning the metal masks or the plating resists to correspond to the conductive pads 120, respectively, but the conductive metal layer may be formed on the entire region in which the solder bumps are to be formed, including the conductive pads 120 and the insulation portions 110, and the conductive metal layer may be melted in heat a treatment. Portions of the melted conductive metal layer may be auto aligned on the conductive pads 120 due to hydrophilicity of a metal forming the conductive pads 120 to thereby form the solder bumps 150, respectively.

In the solder bumps 150 according to the exemplary embodiment of the present inventive concept manufactured as described above, fine processing of the metal masks or the plating resists to correspond to the conductive pads 120, respectively, may not be required in the manufacturing process, a high degree of alignment between the conductive pads 120 and the solder bumps 150 may be secured, and the interval between the solder bumps 150 may be 100 μm or less, that is, a fine pitch between the solder bumps 150 may be achieved.

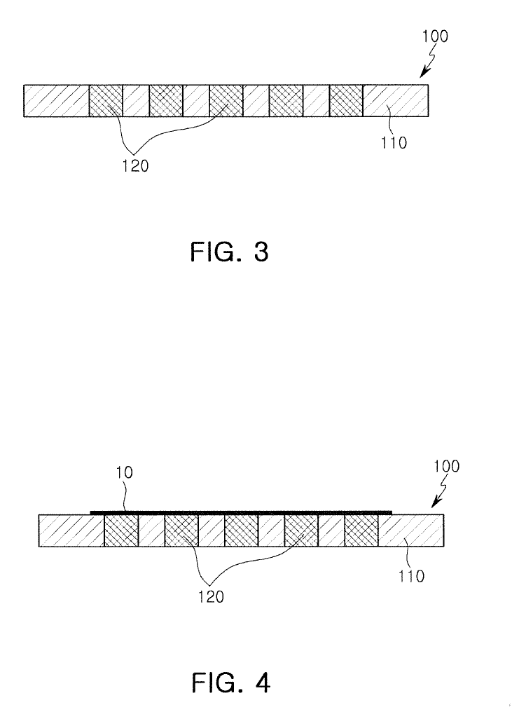

FIGS. 3 through 9 are view illustrating sequential operations of a process of forming solder bumps of a PCB according to exemplary embodiments of the present inventive concept.

Referring to FIGS. 3 through 9, the process of forming the solder bumps 150 of the PCB according to the exemplary embodiment of the present inventive concept will be described in detail.

Referring to FIG. 3, the substrate 100 having the conductive pads 120 exposed on one surface of the substrate 100 may be prepared.

The substrate 100 may include the conductive pads 120 exposed on one surface of the substrate 100 and the insulation portions 110 formed between the conductive pads 120.

Referring to FIG. 4, a base conductive thin film 10 may be formed on the substrate 100 having the conductive pads 120 exposed on one surface of the substrate 100.

The base conductive thin film 10 may be formed in a region in which the solder bumps are to be formed.

The region in which the solder bumps are to be formed may include upper portions of the conductive pads 120 on which the solder bumps are to be formed, respectively, and upper portions of the insulation portions 110 formed between the conductive pads 120 on which the solder bumps are to be formed, respectively.

That is, the base conductive thin film 10 may be formed on the upper portions of the conductive pads 120 on which the solder bumps are to be formed, respectively, and the upper portions of the insulation portions 110 formed between the conductive pads 120, respectively.

The base conductive thin film 10 may be formed by electroless plating or sputtering. However, the manner of forming the base conductive thin film 10 is not necessarily limited thereto.

The base conductive thin film 10 may be formed of conductive metals, for example, at least one selected from the group consisting of Cu, Ag, Au, Al, Fe, Ti, Sn, Ni and Mo.

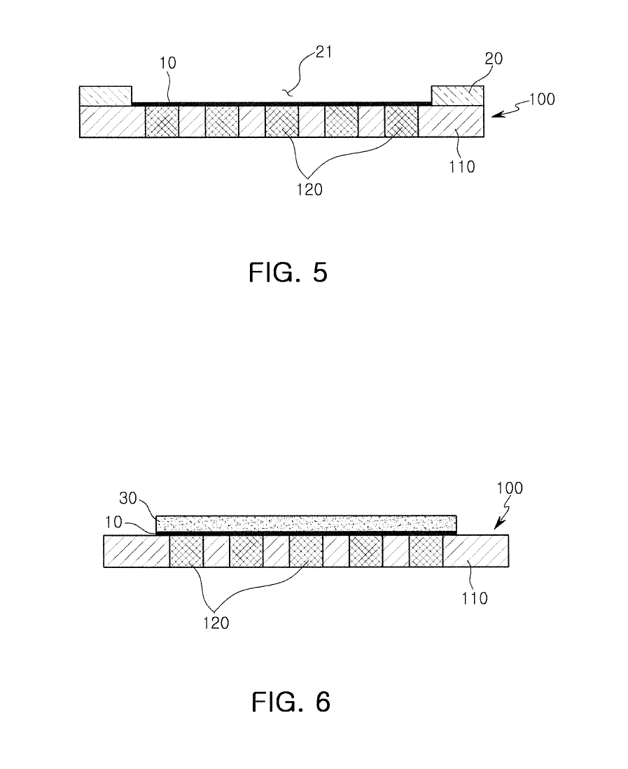

Referring to FIG. 5, a metal mask or a plating resist 20 having an opening portion 21 exposing the region in which the solder bumps are to be formed may be formed.

The metal mask or the plating resist 20 may not be fine processed to correspond to the conductive pads 120, respectively, but maybe formed to have the opening portion 21 exposing the region in which the solder bumps are to be formed, that is, the upper portions of the conductive pads 120 on which the solder bumps are to be formed, respectively, and the upper portions of the insulation portions 110 formed between the conductive pads 120, respectively.

The metal mask may be formed of metal materials, and the plating resist may be general photosensitive resist films such as a dry film resist, and the like. Here, as the dry film, high heat-resistant materials may be used to withstand a subsequent reflow process at a high temperature.

According to a general process of forming circuits by photolithography, the opening portion 21 exposing the region in which the solder bumps are to be formed may be formed.

Referring to FIG. 6, a conductive metal layer 30 may be formed in the region in which the solder bumps are to be formed by filling the opening portion 21.

The conductive metal layer 30 may be formed on the entire region in which the solder bumps are to be formed, that is, the upper portions of the conductive pads 120 on which the solder bumps are to be formed, respectively, and the upper portions of the insulation portions 110 formed between the conductive pads 120, respectively.

In the case in which the metal mask is formed, the conductive metal layer 30 may be formed by filling the opening portion 21 with a solder paste, and in the case in which the plating resist is formed, the conductive metal layer 30 may be formed by filling the opening portion 21 by plating. However, the manner of forming the conductive metal layer 30 is not necessarily limited thereto.

In case in which the conductive metal layer 30 is formed by filling the opening portion 21 with the solder paste, the aformentioned process of forming the base conductive thin film 10 may be omitted.

The conductive metal layer 30 may contain Sn in an amount of 95 wt % or more, and may further contain at least one selected from the group consisting of Cu, Ag, Au, Al, Fe, Ti, Ni and Mo.

Subsequently to the forming of the conductive metal layer 30 by filling the opening portion 21, conductive materials which are not filled in the opening portion 21 but remain on the metal mask or the plating resist 20 may be removed.

Subsequently to the forming of the conductive metal layer 30 by filling the opening portion 21, the metal mask or the plating resist 20 may be removed.

The conductive metal layer 30 may be melted in a heat treatment.

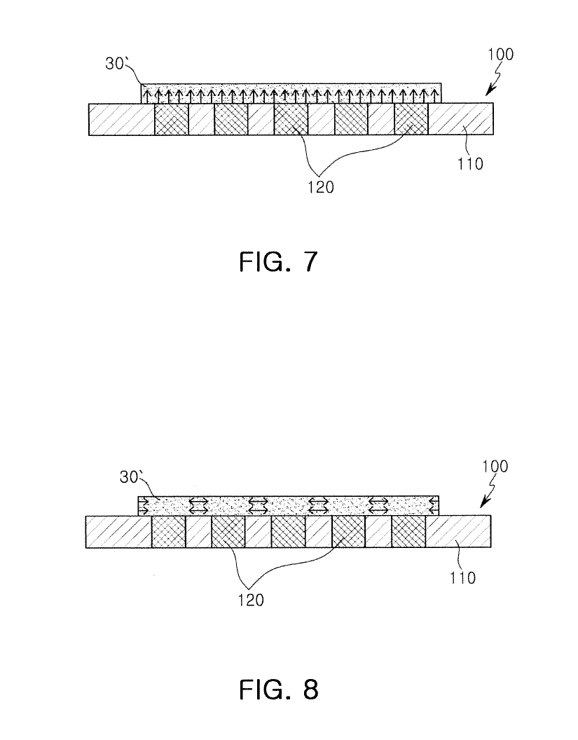

Referring to FIG. 7, the base conductive thin film 10 maybe diffused onto a melted conductive metal layer 30 by the heat treatment.

The base conductive thin film 10 may be melted by the heat treatment, and the melted base conductive thin film may be diffused onto the melted conductive metal layer 30′.

Referring to FIG. 8, portions of the melted conductive metal layer 30′ by the heat treatment may be concentrated on the conductive pads 120, respectively.

A metal forming the conductive pads 120 is relatively hydrophilic, and a resin forming the insulation portion 110 is relatively hydrophobic.

Since the conductive metal layer 30 containing the conductive metal is hydrophilic in a manner similar to that of the conductive pad 120, the portions of the melted conductive metal layer 30′ maybe auto aligned on the conductive pads 120, respectively, due to a concentration property of hydrophilic materials amongst one another.

Meanwhile, the removing of the conductive materials which are not filled in the opening portion 21 but remain on the metal mask or the plating resist 20 may be performed simultaneously with the concentrating of the portions of the conductive metal layer 30′ on the conductive pads 120 in the heat treatment, respectively.

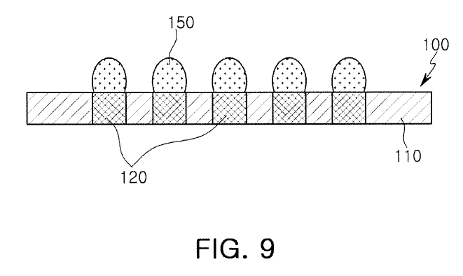

Referring to FIG. 9, the portions of the melted conductive metal layer 30 maybe concentrated on the conductive pads 120 to form the solder bumps 150, respectively.

The portions of the melted conductive metal layer 30′ may be concentrated on the conductive pads 120, respectively, due to hydrophilicity of the metal, and as a temperature is decreased, the solder bumps 150 aligned on the conductive pads 120, respectively, may be formed.

Since the solder bumps 150 formed as above are auto aligned on the conductive pads 120, respectively, due to hydrophilicity of the metal without requiring fine processing on the metal mask or the plating resist to correspond to the conductive pads 120, respectively, a high degree of alignment between the conductive pads 120 and the solder bumps 150 may be secured, and the interval between the solder bumps 150 may be 100 μm or less, that is, a fine pitch between the solder bumps 150 may be achieved.

As set forth above, according to exemplary embodiments of the present inventive concept, a high degree of alignment between the conductive pads and the solder bumps maybe secured, and a fine pitch between the solder bumps may be achieved.

While exemplary embodiments have been shown and described above, it will be apparent to those skilled in the art that modifications and variations could be made without departing from the scope of the invention as defined by the appended claims.

1. A manufacturing method of a printed circuit board (PCB), comprising:
forming a conductive metal layer on a substrate having conductive pads exposed on one surface of the substrate;
melting the conductive metal layer in a heat treatment; and
forming solder bumps by concentrating portions of the melted conductive metal layer on the conductive pads, respectively.

2. The manufacturing method of claim 1, wherein the conductive metal layer is formed in a region in which the solder bumps are to be formed, and the region in which the solder bumps are to be formed includes upper portions of the conductive pads on which the solder bumps are to be formed, respectively, and upper portions of insulation portions formed between the conductive pads on which the solder bumps are to be formed, respectively.

3. The manufacturing method of claim 2, wherein the forming of the conductive metal layer includes:
forming a metal mask having an opening portion exposing the region in which the solder bumps are to be formed; and
filling the opening portion with a solder paste to form the conductive metal layer.

4. The manufacturing method of claim 2, wherein the forming of the conductive metal layer includes:
forming a plating resist having an opening portion exposing the region in which the solder bumps are to be formed; and
filling the opening portion by plating to form the conductive metal layer.

5. The manufacturing method of claim 3, further comprising: susequently to the filling of the opening portion to form the conductive metal layer,
removing conductive materials remaining on the metal mask or the plating resist.

6. The manufacturing method of claim 1, wherein the conductive metal layer contains tin (Sn) in an amount of 95 wt % or more.

7. The manufacturing method of claim 6, wherein the conductive metal layer further contains at least one selected from the group consisting of copper (Cu), silver (Ag), gold (Au), aluminum (Al), iron (Fe), titanium (Ti), nickel (Ni) and molybdenum (Mo).

8. The manufacturing method of claim 1, further comprising: prior to the forming of the conductive metal layer, forming a base conductive thin film on the substrate,
wherein the base conductive thin film is formed in a region in which the solder bumps are to be formed.

9. The manufacturing method of claim 8, wherein the base conductive thin film is formed by electroless plating or sputtering.

10. The manufacturing method of claim 8, wherein the base conductive thin film is diffused onto the conductive metal layer in the heat treatment.

11. The manufacturing method of claim 1, wherein an interval between the solder bumps is 100 micrometers (μm) or less.

12. A printed circuit board (PCB) comprising:
a substrate having conductive pads exposed on one surface of the substrate; and
solder bumps formed on the conductive pads, respectively,
wherein each of the solder bumps has a curved upper surface, and an interval between the solder bumps is 100 micrometers (μm) or less.

13. The PCB of claim 12, wherein the solder bump contains at least one selected from the group consisting of copper (Cu), silver (Ag), gold (Au), aluminum (Al), iron (Fe), titanium (Ti), tin (Sn), nickel (Ni) and molybdenum (Mo).

14. The manufacturing method of claim 4, further comprising: susequently to the filling of the opening portion to form the conductive metal layer,
removing conductive materials remaining on the metal mask or the plating resist.
